(19) United States
(12) Patent Application Publication
(10) Pub. No.: US 2022/0389629 A1
(43) Pub. Date: Dec. 8, 2022

(54) CONDUCTIVE BASE MEMBER AND MULTILAYER CONDUCTIVE BASE MEMBER

(71) Applicant: UNITED PRECISION TECHNOLOGIES CO., LTD., TOKYO (JP)

(72) Inventors: SATOSHI OSAWA, TOKYO (JP); HIDEKI SATO, TOKYO (JP); SHUJI KUNIOKA, TOKYO (JP); HIROKI YOSHIOKA, TOKYO (JP)

(73) Assignee: UNITED PRECISION TECHNOLOGIES CO., LTD., TOKYO (JP)

(21) Appl. No.: 17/776,599

(22) PCT Filed: Nov. 27, 2020
(86) PCT No.: PCT/JP2020/044219

§ 371 Date: May 13, 2022

(30) Foreign Application Priority Data
Nov. 29, 2019 (JP) 2019-217205

(51) Int. Cl. D03D 1/00; H05K 1/02; H01R 13/03; B32B 5/02; B32B 5/26; D03D 15/258; D03D 15/533; D06M 11/83

(52) U.S. Cl. CPC D03D 1/0082; H05K 1/0277; H01R 13/035; B32B 5/022; B32B 5/024; B32B 5/26; D03D 15/258; D03D 15/533; D06M 11/83; B32B 2250/20; B32B 2255/02; B32B 2255/205; B32B 2262/101; B32B 2262/106; B32B 2307/202

(57) ABSTRACT

To provide a flexible conductive base member and a multilayer conductive base member including the same, having no problem of failing to function as a contact and causing a variation in height between contacts.

There are a covered region 10 covered with a noble metal and a non-covered region 20 not circumferentially covered with a noble metal on a surface of a reticulated fibrous body 50. The covered region 10 is located at an intersection 7 of fibers 5 of the reticulated fibrous body 50, and the intersections 7 are connected to each other. The non-covered region 20 is located between the intersections 7 of the fibers 5 of the reticulated fibrous body 50.

### TECHNICAL FIELD

The present invention relates to a conductive base member and a multilayer conductive base member, and particularly to a flexible conductive base member and multilayer conductive base member.

### BACKGROUND ART

Patent Literature 1 discloses a conductive connector as a conductive multi-contact connector, in which a metal circuit is formed on a woven fabric made of fibers, and noble metal plating for a contact is performed on both surfaces or one surface of an intersection protrusion that is a lattice-shaped weave in the metal circuit formed on the woven fabric in order to avoid an increase in the amount of gold used during gold plating due to the planar shape of a conventional conductive connector.

Patent Literature 2 discloses a conductive circuit board having an opening, in which in order to provide a flexible circuit board that can be freely bent at a wide range angle without peeling of a circuit from a base material, a conductive circuit is integrally formed by growth of plating on a surface of a fibrous base material having an opening made of a woven fabric or a nonwoven fabric or a porous sheet having a large number of both-side through-microholes while the conductive circuit is entangled with gaps of the fibrous base material or the through-microholes of the porous sheet, the plating is thereby grown, and a conductive circuit itself formed on the conductive circuit has an opening.

Patent Literature 1: JP 5512245 B2

Patent Literature 2: JP 5377588 B2

### SUMMARY OF INVENTION

### Technical Problem

However, the conductive connector disclosed in Patent Literature 1 has a problem that a load applied to noble metal plating of the intersection protrusion is large to peel off the plating during use, and the conductive connector does not function as a contact.

In addition, the conductive circuit board disclosed in Patent Literature 2 has a problem that it is difficult to control the degree of growth of plating, as a result, plating is not performed uniformly, and a variation in height between contacts occurs due to instability of the plating thickness to cause a difference in the amount of current.

Therefore, an object of the present invention is to provide a flexible conductive base member and a multilayer conductive base member including the same by an approach different from the techniques disclosed in Patent Literatures 1 and 2.

### Solution to Problem

In order to solve the above problems, a conductive base member of the present invention has:

a covered region covered with a noble metal; and a non-covered region not covered with a noble metal on a surface of a reticulated fibrous body,

the covered region is formed at an intersection of fibers of the reticulated fibrous body, and the intersection is electrically short-circuited, and

the non-covered region is formed between the intersections of the fibers of the reticulated fibrous body, and the portion between the intersections is electrically opened.

Note that the non-covered region can be formed by chemical treatment or mechanical treatment.

The reticulated fibrous body may be a fibrous body in which a non-covered region is formed on a noble metal fiber covered with a noble metal.

In addition, the reticulated fibrous body may be a fibrous body in which a non-covered region is formed between intersections of noble metal fibers covered with a noble metal on a mixture of the noble metal fibers and a non-noble metal fiber not covered with a noble metal.

Furthermore, the reticulated fibrous body may be a fibrous body in which, on a fibrous body of a non-noble metal fiber not covered with a noble metal covered with a noble metal, a non-covered region is formed between intersections of fibers of the fibrous body covered with the noble metal.

In addition, a multilayer conductive base member of the present invention is formed by stacking the conductive base member.

### DESCRIPTION OF EMBODIMENTS

Hereinafter, an embodiment of the present invention will be described with reference to the drawings.

FIG. 1 is a perspective view in which a part of a conductive base member 100 according to an embodiment of the present invention is extracted. As illustrated in FIG. 1, the conductive base member 100 of the present embodiment includes a reticulated fibrous body 50. The reticulated fibrous body 50 may be a woven fabric, a nonwoven fabric, or a material similar thereto, for example, an insulating material.

The reticulated fibrous body 50 is constituted by a plurality of fibers 5 arranged in a lattice pattern. The fiber 5 itself only needs to be an insulating material (non-conductive fiber) having flexibility, and for example, a fiber appropriately selected from a glass fiber, a chemical fiber, a carbon fiber, and the like can be used.

A surface of each fiber 5 is roughly classified into a covered region 5 (10) (hereinafter, the reference numeral assigned to this region in the present specification is simply “10”) covered with a noble metal and a non-covered region 20 (hereinafter, the reference numeral assigned to this region in the present specification is simply “20”) at least not circumferentially covered with a noble metal. As the noble metal herein, a metal having conductivity, such as gold, silver, or platinum, can be used.

The specifications of the fiber 5, such as a diameter and a strength, are not particularly limited, but a fiber having a diameter of about 5 μm to 100 μm and a hardness of 1 or more can be appropriately selected.

As illustrated in FIG. 1, either the covered region 10 or the non-covered region 20 is formed on a surface of the fiber 5. Specifically, the covered region 10 is formed at an intersection 7 of the fibers 5 orthogonal to each other, and the intersection 7 is electrically short-circuited. Meanwhile, the non-covered region 20 is formed between the intersections 7 adjacent to each other, and the portion between the intersections 7 is electrically opened.

However, the covered region 10 does not necessarily need to be formed at each of the intersections 7, and the non-covered region 20 does not necessarily need to be formed at every portion between the intersections 7. For example, by forming the covered region 10 at any two or more adjacent intersections 7 and between them, a relatively wide contact region such as a pad can be obtained. On the other hand, by forming the non-covered region 20 at any two or more adjacent intersections 7 and between them, a relatively wide non-contact region can be obtained.

At the intersection 7 of the fibers 5 at which the covered region 10 is located, the fibers 5 come into contact with each other at least during use of the conductive base member 100. A step of forming the covered region 10 on the fiber 5 may be performed before or after formation of the reticulated fibrous body 50 as described in the following Examples.

In addition, a method for forming the covered region 10 is not limited, and for example, the covered region 10 only needs to be formed by bringing the fiber 5 itself or the reticulated fibrous body 50 into contact with a noble metal plating solution or s noble metal gas corresponding to the covered region 10.

Each intersection 7 at which the covered region 10 is formed comes into contact with an electrode or the like of an electronic component (not illustrated). A portion between the intersections 7 at which the non-covered region 20 is formed is insulated.

As described above, each intersection 7 on the surface of each fiber 5 is covered with a noble metal, and is electrically short-circuited. Meanwhile, a portion between the intersections 7 adjacent to each other is not covered with a noble metal, and is electrically opened.

In the present embodiment, the non-covered region 20 is formed by, for example, etching a portion that is initially the covered region 10 using an etching solution corresponding to the noble metal of the covered region 10. However, in this case, it is necessary to use an etching solution having a condition under which the fiber 5 itself is not dissolved.

In addition, the non-covered region 20 does not necessarily need to be formed by etching, and may be formed by chemical treatment other than etching, or for example, mechanical treatment such as sandblasting or ion irradiation.

Hereinafter, the conductive base member 100 of the present invention and a multilayer conductive base member including the same will be described using Examples.

### EXAMPLES

In the conductive base member 100 of Examples of the present invention, the reticulated fibrous body 50 can be manufactured according to several aspects as described in Examples. Hereinafter, a process of manufacturing the conductive base member 100 of each Example will be described.

### Example 1

FIG. 2 is an explanatory view of a conductive base member 100 of Example 1 of the present invention. In the present Example, first, a noble metal fiber 1 covered with a noble metal is prepared as a precursor of a fiber 5 (FIG. 2(a)).

Then, the noble metal fiber 1 is appropriately interwoven in a lattice shape to manufacture a reticulated fibrous body 50A constituted by the fiber 5 (FIG. 2(b)).

Therefore, the entire surface of the fiber 5 constituting the reticulated fibrous body 50A is covered with the noble metal, and only a covered region 10 is formed.

Next, for example, each intersection 7 of the fibers 5 is, for example, masked with a resist, and then the fibers 5 are doped with an etching solution to, for example, etch a portion between the intersections 7 of the fibers 5. As a result, the noble metal of the relevant portion is dissolved to form a non-covered region 20 (FIG. 2(c)).

As a result, as described with reference to FIG. 1, the covered region 10 and the non-covered region 20 are formed on the reticulated fibrous body 50A.

In the present Example, as compared with Example 2 described later, a distance between the intersections 7 adjacent to each other of the fibers 5 is short, and therefore there is an advantage that the number of the intersections 7 of the fibers 5 per unit area can be increased.

### Example 2

FIG. 3 is an explanatory view of a conductive base member 100 of Example 2 of the present invention. In the present Example, as a precursor of a fiber 5, a noble metal fiber 1 covered with a noble metal and a non-noble metal fiber 3 including an insulating fiber or a metal fiber such as copper, not covered with a noble metal, are prepared (FIG. 3(a)).

Then, the noble metal fiber 1 and the non-noble metal fiber 3 are appropriately interwoven in a lattice shape to manufacture a reticulated fibrous body 50B (FIG. 3(b)).

Therefore, about a half of a surface of the fiber 5 constituting the reticulated fibrous body 50B is partially covered with the noble metal, and a covered region 10 and a non-covered region 20 are formed in a mixed manner.

Note that, as an example, the noble metal fiber 1 can be assigned to the fibers 5 in an odd-numbered row and an odd-numbered column, and the non-noble metal fiber 3 can be assigned to the fibers 5 in an even-numbered row and an even-numbered column. As another example, the fibers 5 in a row of a multiple of 3 and a column of a multiple of 3 can be the noble metal fibers 1, and the fibers 5 in the other rows and the other columns can be the non-noble metal fibers 3.

In the present Example, each intersection 7 of the noble metal fibers 1 is, for example, masked with a resist, and then the noble metal fibers 1 are doped with an etching solution to, for example, etch a portion between the intersections 7 of the noble metal fibers 1. As a result, the noble metal of the relevant portion is dissolved to form a non-covered region 20 (FIG. 3(c)).

To be sure, the etching target in the present Example only needs to be able to insulate the intersections 7 of the noble metal fibers 1 from each other, and therefore can be only intersections of the non-noble metal fibers 3 orthogonal to each other.

In the conductive base member 100 of the present Example, as compared with that of Example 1, the non-noble metal fiber 3 is located between the intersections 7 adjacent to each other of the noble metal fibers 1, and thus a region to be etched is sufficiently secured. Therefore, there is an advantage that the etching treatment including the masking treatment is easily performed.

### Example 3

FIG. 4 is an explanatory view of a conductive base member 100 of Example 3 of the present invention. In the present Example, instead of preparing a fiber 5 itself, a reticulated fibrous body 50C into which a non-noble metal fiber 3 is already interwoven is prepared (FIG. 4(a)).

That is, as the reticulated fibrous body 50C, it is typically only required to prepare a general-purpose cloth. Therefore, the entire surface of a fiber 5 constituting the reticulated fibrous body 50C is not covered with a noble metal, which means that only a non-covered region 20 is formed.

However, the reticulated fibrous body 50C needs to be a cloth or the like made of a fiber of a material that is not inhibited when the non-noble metal fiber 3 is formed. Specifically, when the non-noble metal fiber 3 is formed by etching, the reticulated fibrous body 50C needs to be a cloth or the like made of a fiber of a material that is not dissolved in an etching solution.

Then, the reticulated fibrous body 50C is, for example, doped with a noble metal plating solution for a predetermined time, and the whole of the reticulated fibrous body 50C is covered with a noble metal. Therefore, the entire surface of the fiber 5 constituting the reticulated fibrous body 50C is covered with the noble metal, and only a covered region 10 is formed. (FIG. 4(b)).

Therefore, each intersection 7 of the noble metal fibers 1 is, for example, masked with a resist, and then the noble metal fibers 1 are doped with an etching solution to, for example, etch a portion between the intersections 7. As a result, the noble metal of the relevant portion is dissolved to form a non-covered region 20 (FIG. 4(c)).

As a result, as described with reference to FIG. 1, the covered region 10 and the non-covered region 20 are formed on the reticulated fibrous body 50C.

In the conductive base member 100 of the present Example, as compared with that of Example 1, the existing general-purpose reticulated fibrous body 50C can be covered with a desired noble metal, and therefore there is an advantage that the degree of freedom in selecting a noble metal increases.

### Example 4

FIG. 5 is a side view of a multilayer conductive base member 200 including a plurality of the conductive base members 100 described with reference to FIG. 2. Note that the multilayer conductive base member 200 may include a plurality of only the conductive base members 100 described with reference to FIG. 3 or 4, or may include a plurality of appropriately combined conductive base members 100 described with reference to FIGS. 2 to 4.

The multilayer conductive base member 200 is obtained by connecting the plurality of conductive base members 100 to each other in a state where the conductive base members 100 are aligned. For connecting the conductive base members 100 to each other, for example, it is only required to connect intersections 7 of the noble metal fibers 1 at corresponding positions of the conductive base members 100 to each other using an adhesive 9, solder, or the like.

As described above, the present invention can provide a flexible conductive base member and a multilayer conductive base member including the same, having no problem of failing to function as a contact and causing a variation in height between contacts.

### BRIEF DESCRIPTION OF DRAWINGS

FIG. 1 is a perspective view in which a part of a conductive base member 100 according to an embodiment of the present invention is extracted.

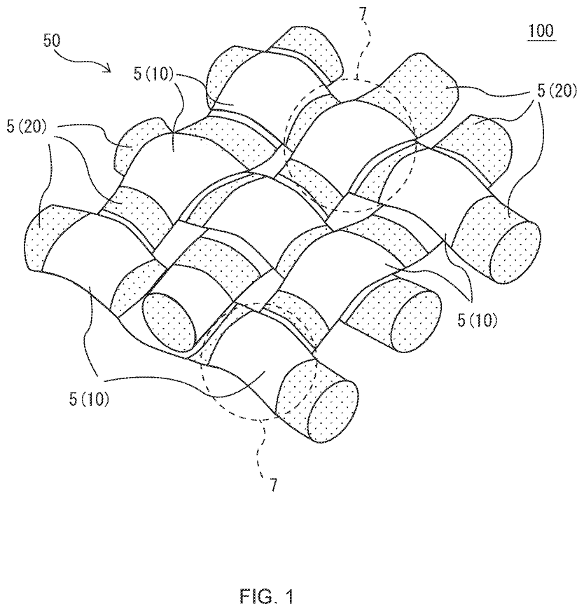

FIG. 2 is an explanatory view of a conductive base member 100 of Example 1 of the present invention.

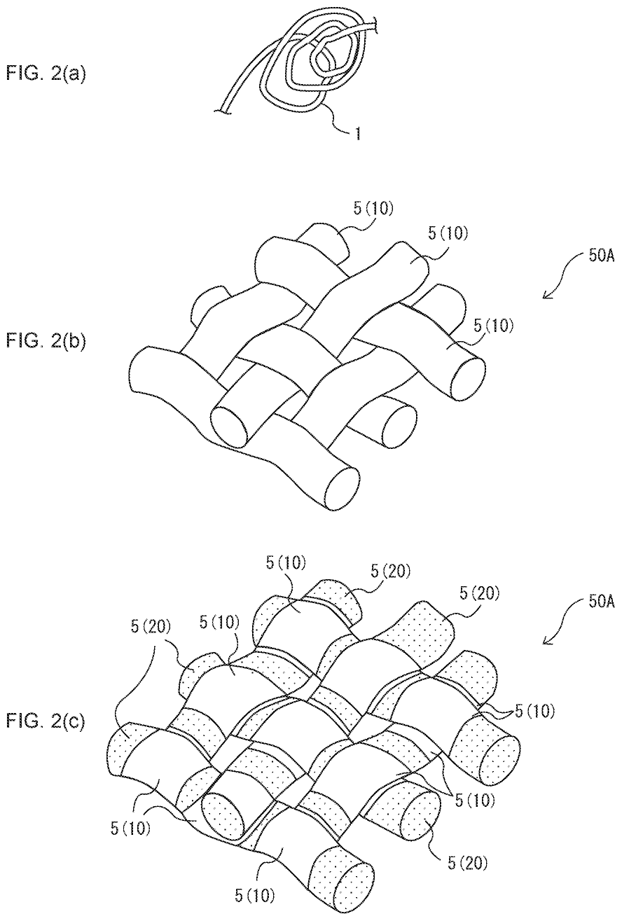

FIG. 3 is an explanatory view of a conductive base member 100 of Example 2 of the present invention.

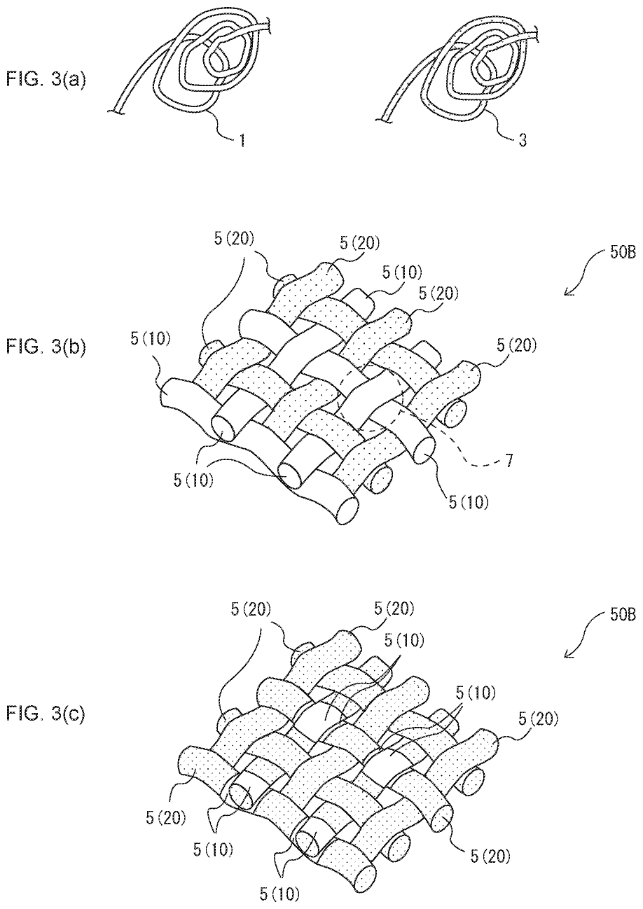

FIG. 4 is an explanatory view of a conductive base member 100 of Example 3 of the present invention.

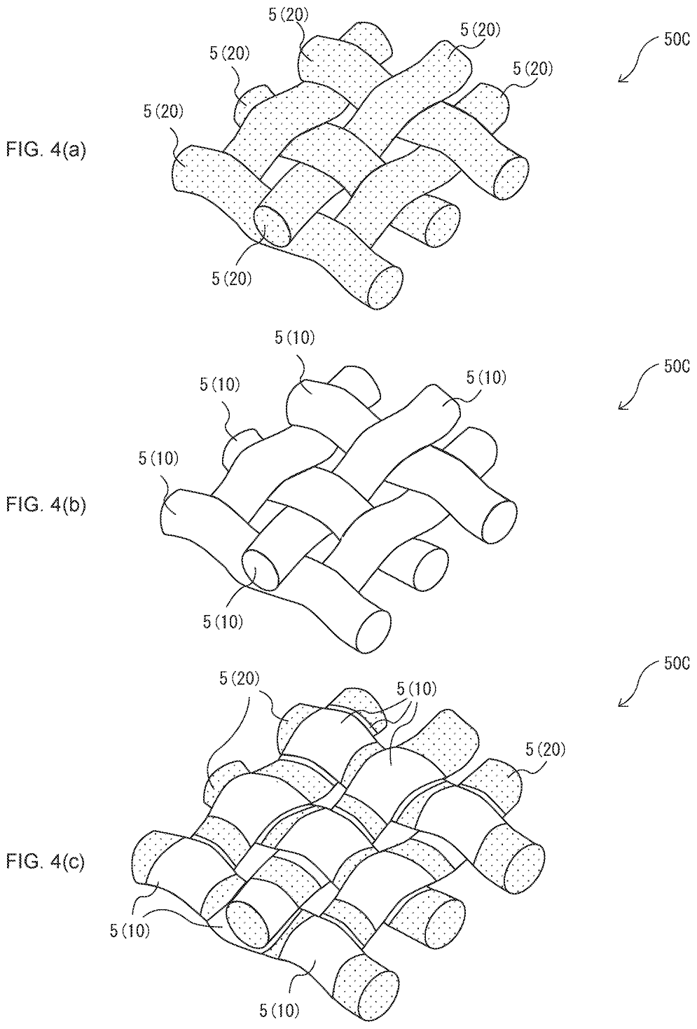

FIG. 5 is a side view of a multilayer conductive base member 200 including a plurality of the conductive base members 100 described with reference to FIG. 2.

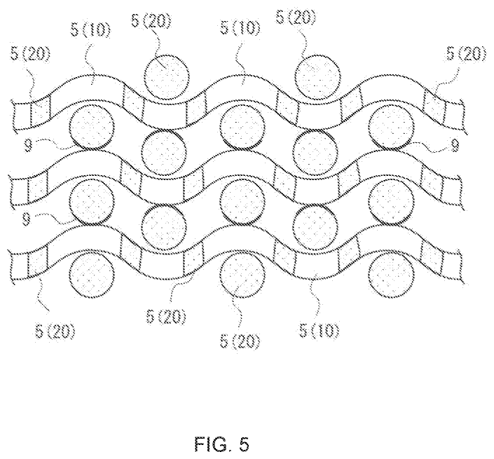

### REFERENCE SIGNS LIST

1 Noble metal fiber
3 Non-noble metal fiber
5 Fiber
7 Intersection
9 Adhesive
10 Covered region
20 Non-covered region
50, 50A, 50B, 50C Reticulated fibrous body
100 Conductive base member
200 Multilayer conductive base member

1. A conductive base member comprising:
a covered region covered with a noble metal; and a non-covered region not covered with a noble metal on a surface of a reticulated fibrous body, wherein
the covered region is formed at an intersection of fibers of the reticulated fibrous body, and the intersection is electrically short-circuited, and
the non-covered region is formed between the intersections of the fibers of the reticulated fibrous body, and the portion between the intersections is electrically opened.

2. The conductive base member according to claim 1, wherein the non-covered region is formed by chemical treatment or mechanical treatment.

3. The conductive base member according to claim 1, wherein the reticulated fibrous body is a fibrous body in which a non-covered region is formed on a noble metal fiber covered with a noble metal.

4. The conductive base member according to claim 1, wherein the reticulated fibrous body is a fibrous body in which a non-covered region is formed between intersections of noble metal fibers covered with a noble metal on a mixture of the noble metal fibers and a non-noble metal fiber not covered with a noble metal.

5. The conductive base member according to claim 1, wherein the reticulated fibrous body is a fibrous body in which, on a fibrous body of a non-noble metal fiber not covered with a noble metal covered with a noble metal, a non-covered region is formed between intersections of fibers of the fibrous body covered with the noble metal.

6. A multilayer conductive base member formed by stacking the conductive base member according to claim 1.
